(19) United States
(12) Patent Application Publication
(10) Pub. No.: US 2024/0222183 A1
(43) Pub. Date: Jul. 4, 2024

(54) CROSSLINKING A BACK GRINDING TAPE FOR A SEMICONDUCTOR WAFER

(71) Applicant: Micron Technology, Inc., Boise, ID (US)

(72) Inventors: Ankur Harish SHAH, Singapore (SG); Venkateswarlu BHAVANASI, Singapore (SG); Wen How SIM, Singapore (SG); Harjashan Veer SINGH, South Richmond Hill, NY (US)

(21) Appl. No.: 18/390,795

(22) Filed: Dec. 20, 2023

Related U.S. Application Data
(60) Provisional application No. 63/478,266, filed on Jan. 3, 2023.

(51) Int. Cl. H01L 21/683; H01L 21/304

(52) U.S. Cl. CPC H01L 21/6836; H01L 21/304; H01L 2221/68327; H01L 2221/68386

(57) ABSTRACT

Implementations described herein relate to various semiconductor device assemblies and methods of forming the same. In some implementations, a semiconductor assembly may include a semiconductor wafer including a face including one or more circuit elements and a back grinding tape adhered to the face. The back grinding tape may include a polymer base layer and an adhesive layer adhering the back grinding tape to the face of the semiconductor wafer, and the back grinding tape may exhibit a damping ratio of less than approximately 0.8. The back grinding tape may include at least one of infrared-activated crosslinking groups or thermally activated crosslinking groups such that a degree of crosslinking associated with the back grinding tape may vary according to at least one of an amount of heat applied to the back grinding tape or an amount of infrared radiation applied to the back grinding tape.

### CROSS REFERENCE TO RELATED APPLICATION

This patent application claims priority to U.S. Provisional Patent Application No. 63/478,266, filed on Jan. 3, 2023, and entitled “CROSSLINKING A BACK GRINDING TAPE FOR A SEMICONDUCTOR WAFER.” The disclosure of the prior application is considered part of and is incorporated by reference into this patent application.

### TECHNICAL FIELD

The present disclosure generally relates to semiconductor devices and methods of forming semiconductor devices. For example, the present disclosure relates to crosslinking a back grinding tape for a semiconductor wafer.

### BACKGROUND

A semiconductor package includes a casing that contains one or more semiconductor devices, such as integrated circuits. Semiconductor device components may be fabricated on semiconductor wafers before being diced into die and then packaged. A semiconductor package protects internal components from damage and includes means for connecting internal components to external components (e.g., a circuit board), such as via balls, pins, or leads. A semiconductor package is sometimes referred to as a semiconductor device assembly.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram of an example back grinding process that may be used to create a semiconductor die.

FIGS. 4A-4F show an example back grinding process using a crosslinked back grinding tape that may be used to create a semiconductor die with a reduced total thickness variation.

FIG. 5 is a diagram of an example associated with varying a crosslinking density according to a type of semiconductor die being formed by a semiconductor wafer.

FIG. 6 is a diagram of example equipment used to manufacture various semiconductor packages, memory devices, or similar components described herein.

FIG. 7 is a flowchart of an example method of forming an integrated assembly or memory device having a reduced total thickness variation.

FIG. 8 is a flowchart of an example method of forming an integrated assembly or memory device having a reduced total thickness variation.

### DETAILED DESCRIPTION

Back grinding tape may be used to protect certain components of a semiconductor wafer (e.g., circuit components or similar components) during a back grinding process (sometimes referred to as a wafer lapping process, a back finishing process, or a wafer thinning process). Back grinding may be used during semiconductor-wafer fabrication to reduce a thickness of a semiconductor wafer, such as for purposes of creating thin, stackable semiconductor dies and/or to enable high-density integrated circuit (IC) packages. Prior to back grinding, the semiconductor wafer may be laminated with a back grinding tape, such as a pressure sensitive adhesive back grinding tape, an ultraviolet (UV) curable back grinding tape, or a similar back grinding tape. For example, the back grinding tape may be laminated on a side of the semiconductor wafer that includes circuit elements, such as bond pads, bumps, or other electrical contacts. The back grinding tape may protect the circuit components during the back grinding process, ensure against semiconductor wafer surface damage during the back grinding process, and/or prevent semiconductor wafer surface contamination caused by infiltration of grinding fluid and/or other contaminants during the back grinding process.

In some examples, a semiconductor wafer may be back grinded in order to produce ultra-thin dies. Ultra-thin dies may be associated with thicknesses of less than approximately 60 micrometers (μm). In such examples, variation in a thickness of the ultra-thin dies (sometimes referred to a total thickness variation (TTV)) may greatly impact performance of the die. TTV may refer to a difference between maximum and minimum values of thicknesses measured on the semiconductor die, such as during a scan pattern, a series of point measurements, or other measurement process. For example, a TTV of as little as ±3 μm in an ultra-thin die may represent a variation of up to 10% in the die's total thickness, which may adversely impact a loadbearing capacity of the die and/or may result in a low failure load associated with the die. Moreover, high TTVs may impact the ability of multiple dies to be stacked on each other, such as multiple memory dies forming a memory die stack in a multi-chip package (MCP) or similar semiconductor package, because high TTVs may result in uneven stacking, bulging of the package, and/or similar defects.

Additionally, a TTV of a back grinding tape used during a back grinding process may contribute to overall semiconductor wafer TTV. More particularly, using back grinding tapes associated with relatively high TTVs may result in semiconductor wafers exhibiting high TTV following a back grinding process. As a result, as dies become thinner and thinner, high TTVs associated with back grinding tapes may become more problematic, resulting in high TTVs of grinded wafers, resulting in high failure rates and dies unsuitable for use in MCPs and similar semiconductor packages.

Some implementations described herein enable a reduced back grinding tape TTV by forming a viscoelastic base layer that may be crosslinked to various degrees when subjected to pressure, heat, infrared light, or similar stimulants, thereby resulting in a suitable back grinding tape for use in creating ultra-thin dies and other semiconductor components. For example, the back grinding tape may include a damping ratio of less than approximately 0.8, such that the tape may conform to certain circuit elements on a semiconductor wafer and/or such that the back grinding tape may be suitably flattened by applying pressure to the tape. Additionally, or alternatively, the back-grinding tape may include at least one of infrared-activated crosslinking groups or thermally activated crosslinking groups, such that a degree of crosslinking associated with the back grinding tape may be varied according to an amount of heat applied to the back grinding tape and/or an amount of infrared light applied to the back grinding tape. By crosslinking the back grinding tape via heat, infrared light, or similar stimulants, the back grinding tape may become more rigid and thus exhibit a reduced TTV.

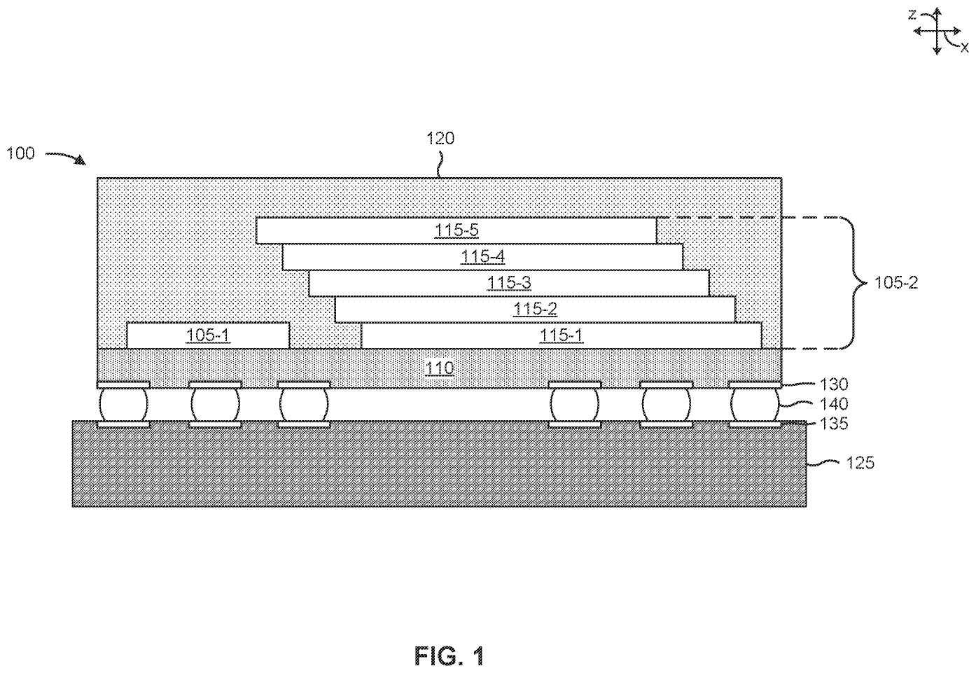

In some implementations, the back grinding tape may be mounted to a circuit side of a semiconductor wafer, crosslinked to increase a rigidity and/or to reduce a TTV associated with the back grinding tape, and then removed following a back grinding process, resulting in a reduced TTV of the back-grinded semiconductor wafer as compared to a TTV of back-grinded semiconductor wafers formed using traditional back grinding tapes. As a result, the back grinding tape may be suitable for use to create ultra-thin dies associated with reduced TTVs, increased loadbearing capacity, or reduced failure rates, among other benefits. Additionally, the back grinding tape may be tunable to achieve certain target TTVs by varying a degree to which the back grinding tape is crosslinked, resulting in a back grinding tape that is adapted for use for various devices and applications. These and other features may be more readily understood with reference to FIGS. 1-8, described in detail below.

FIG. 1 is a diagram of an example apparatus 100 that may be manufactured using techniques described herein.

In FIG. 1 and the figures that follow, each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a synchronous dynamic RAM (SDRAM) device, a ferroelectric RAM (FeRAM) device, a magnetic RAM (MRAM) device, a resistive RAM (RRAM) device, a holographic RAM (HRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include multiple semiconductor dies 115 (sometimes called dies), shown as five semiconductor dies 115-1 through 115-5. As shown in FIG. 1, the dies 115 may be stacked on top of each other to reduce a footprint of the apparatus 100. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on.

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As indicated above, FIG. 1 is provided as an example. Other examples may differ from what is described with regard to FIG. 1.

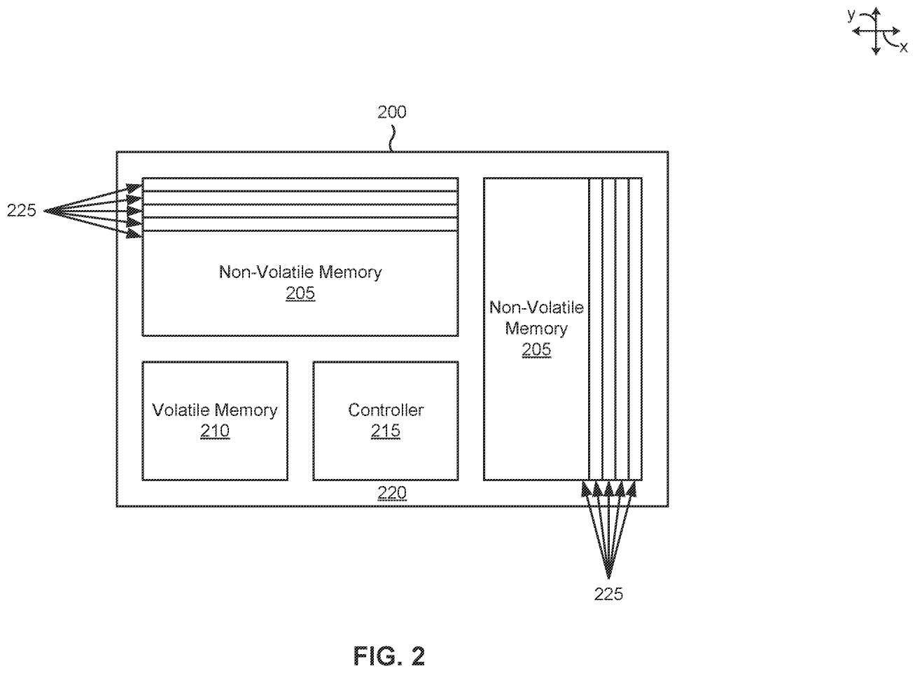

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, an embedded multimedia card (eMMC) device, a managed NAND (mNAND) device, and/or an MCP.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes stacked semiconductor dies 225, as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

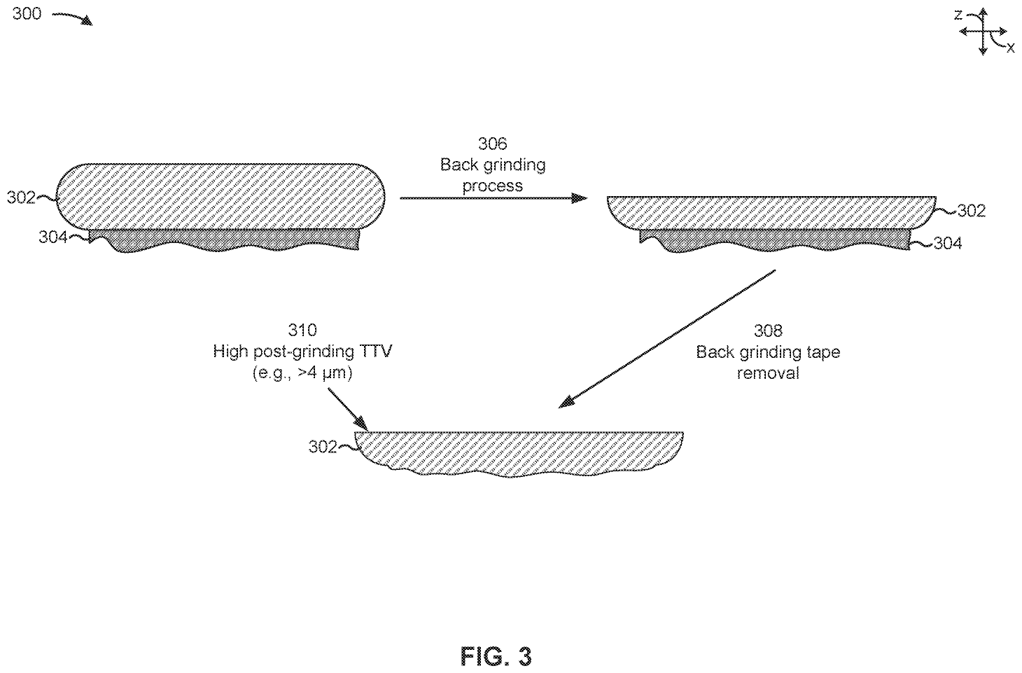

FIG. 3 is a diagram of an example back grinding process 300 that may be used to create a semiconductor die.

As shown in FIG. 3, a semiconductor wafer 302 may be mounted to a back grinding tape 304 prior to a back grinding process. In some examples, the back grinding tape may include a polymer base layer, such as a polyethylene terephthalate (PET) composite layer, and an adhesive layer, such as a UV-curable, acrylic adhesive layer. In such examples, the back grinding tape 304 may be adhered to the semiconductor wafer 302 via the adhesive layer. More particularly, the back grinding tape 304 may be adhered to a face of the semiconductor wafer 302 that includes one or more circuit elements, such as bond pads, bumps, or similar electrical contacts. In that regard, the back grinding tape 304 may protect the one or more circuit elements during a back grinding process of the semiconductor wafer 302.

As shown in FIG. 3, when adhered to the semiconductor wafer 302, the back grinding tape 304 may have an irregular thickness (e.g., a dimension in the z-axis direction). This may be due to the back grinding tape 304 encompassing the one or more circuit elements and/or due to a TTV associated with the back grinding tape. In some examples, the irregular thickness of the back grinding tape 304 (e.g., the high TTV of the back grinding tape 304) may result in a high post-grinding TTV of the semiconductor wafer 302.

More particularly, as shown by reference number 306, the semiconductor wafer may be subject to a back grinding process in order to reduce the overall thickness of the semiconductor wafer 302 (e.g., a dimension of the semiconductor wafer 302 in the z-axis direction). For example, prior to back grinding, the semiconductor wafer 302 may be approximately 900 μm thick, and the back grinding process may be used to reduce the thickness to less than approximately 100 μm thick (e.g., less than approximately 60 μm thick for ultra-thin dies). In some examples, the semiconductor wafer 302 may be back grinded to approximately 100 μm thick when used to create memory controller dies (e.g., controllers 215), the semiconductor wafer 302 may be back grinded to approximately 60 μm thick when used to create DRAM memory dies (e.g., volatile memory 210 dies), and the semiconductor wafer 302 may be back grinded to approximately 60 μm thick when used to created NAND memory dies (e.g., non-volatile memory 205 dies).

In some examples, back grinding may include multiple grinding steps. For example, the semiconductor wafer 302 may undergo a rough grinding step, a fine grinding step, a super-fine grinding step, and/or a chemical and/or mechanical polishing step. In some examples, the semiconductor wafer 302 may be placed on a rotary table in a wafer back grinding machine with a backside of the semiconductor wafer 302 (e.g., a face of the semiconductor wafer 302 opposite to the face on which the back grinding tape 304 is mounted) facing upwards and/or toward a grinding wheel of the wafer back grinding machine. The grinding wheel may be rotated to grind the backside of the semiconductor wafer 302. In some cases, following grinding, a polishing wheel may be used to polish the rough-grinded backside of the semiconductor wafer 302, resulting in the thinned semiconductor wafer 302.

As shown by reference number 308, following the back grinding process, the back grinding tape 304 may be removed from the semiconductor wafer 302. In some examples, the back grinding tape 304 may include a UV-curable adhesive layer. In such examples, removing the back grinding tape may include subjecting the back grinding tape to UV light, thereby causing the adhesive layer to cure so the back grinding tape 304 may be easily peeled from the semiconductor wafer 302 without damaging components of the semiconductor wafer 302 (e.g., without damaging the one or more circuit elements of the semiconductor wafer 302).

As shown by reference number 310, following removal of the back grinding tape 304, the semiconductor wafer 302 may exhibit a high post-grinding TTV, such as a TTV of greater than 4 μm for ultra-thin dies (e.g., dies less than approximately 60 μm thick). In some aspects, the high post-grinding TTV may be based at least in part on the high TTV associated with the back grinding tape 304. This high post-grinding TTV may result in a reduced load bearing capacity of dies diced from the semiconductor wafer 302 and/or a low failure load associated with dies diced from the semiconductor wafer 302, and/or may result in dies having dimensions that are insufficient for use in die stacks and/or MCPs.

As indicated above, FIG. 3 is provided as an example. Other examples may differ from what is described with regard to FIG. 3.

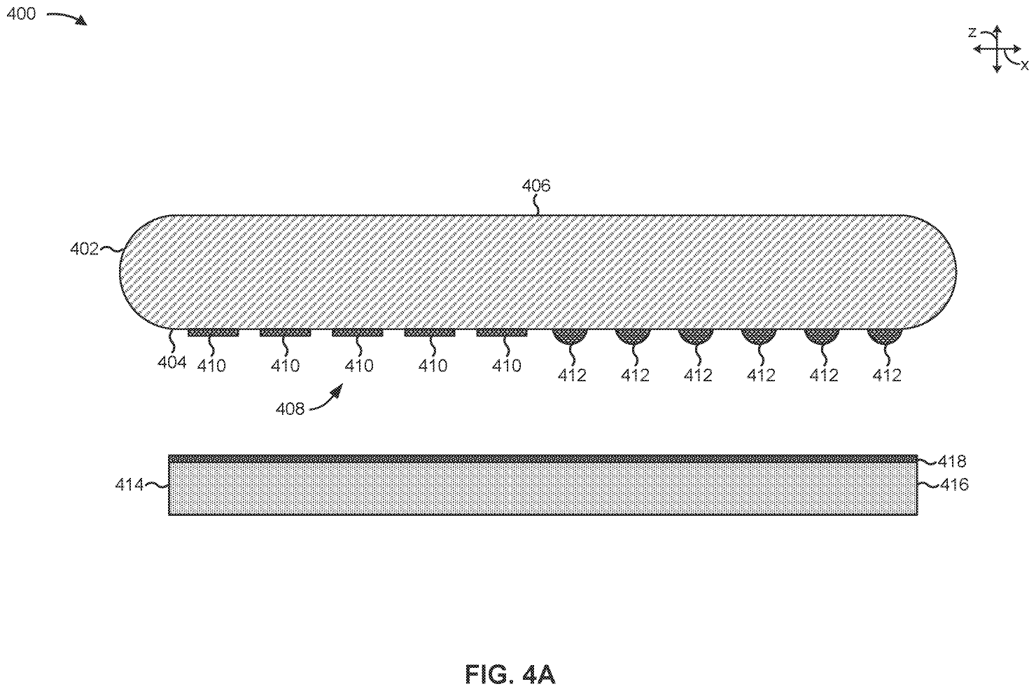

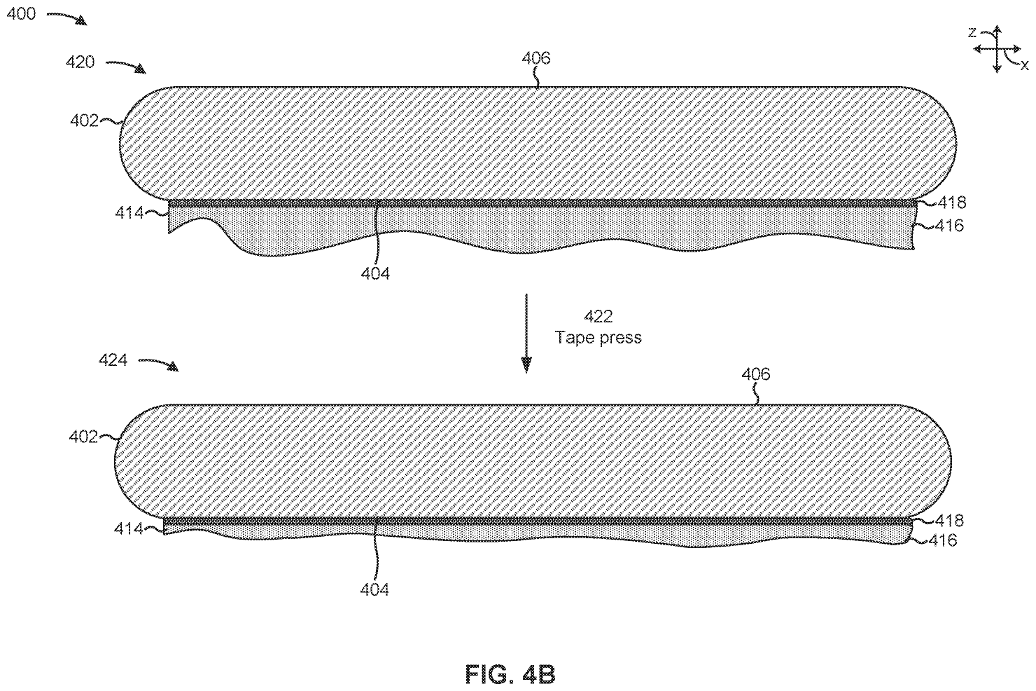

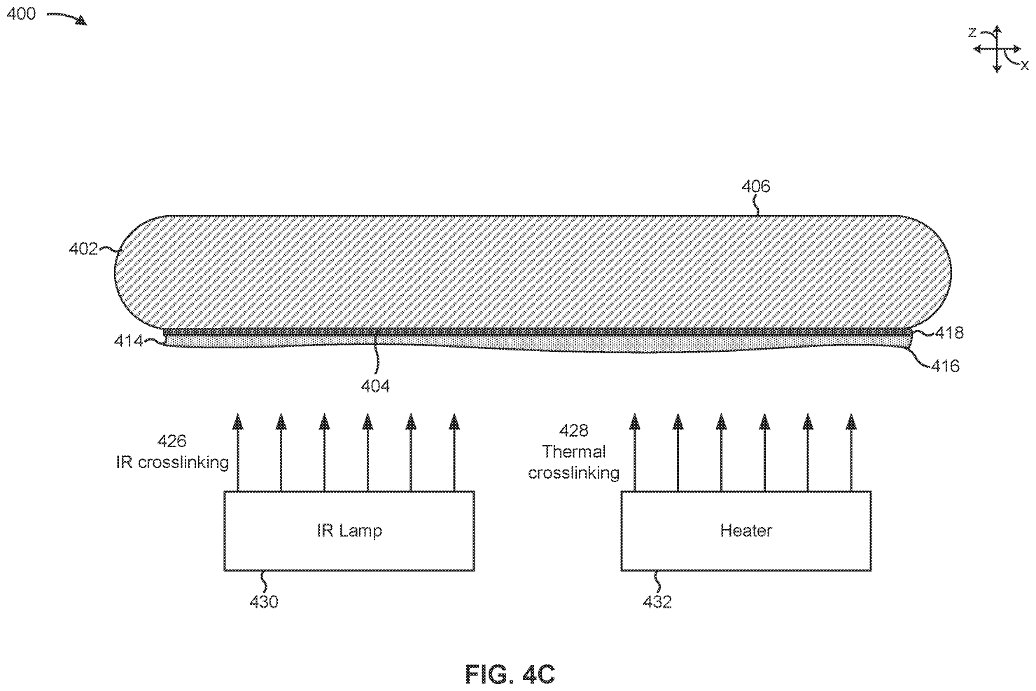

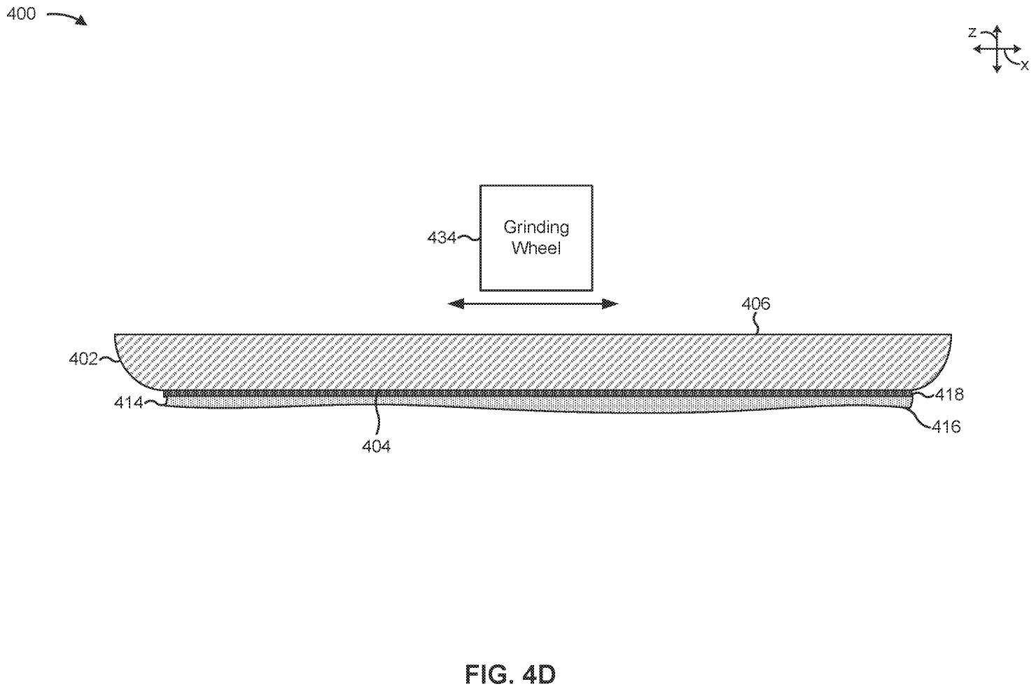

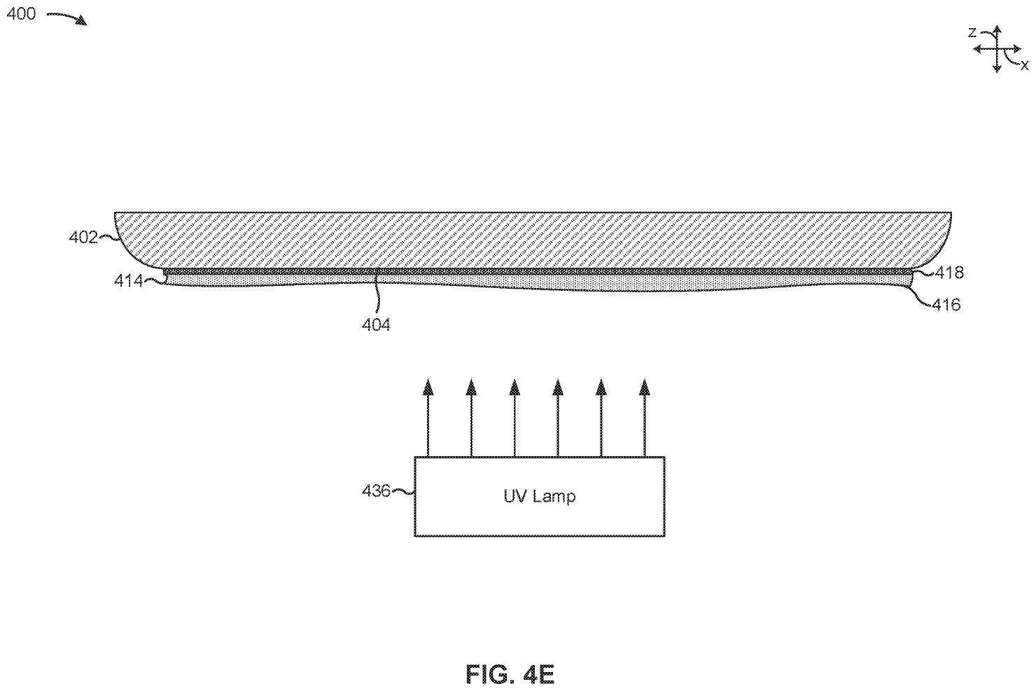

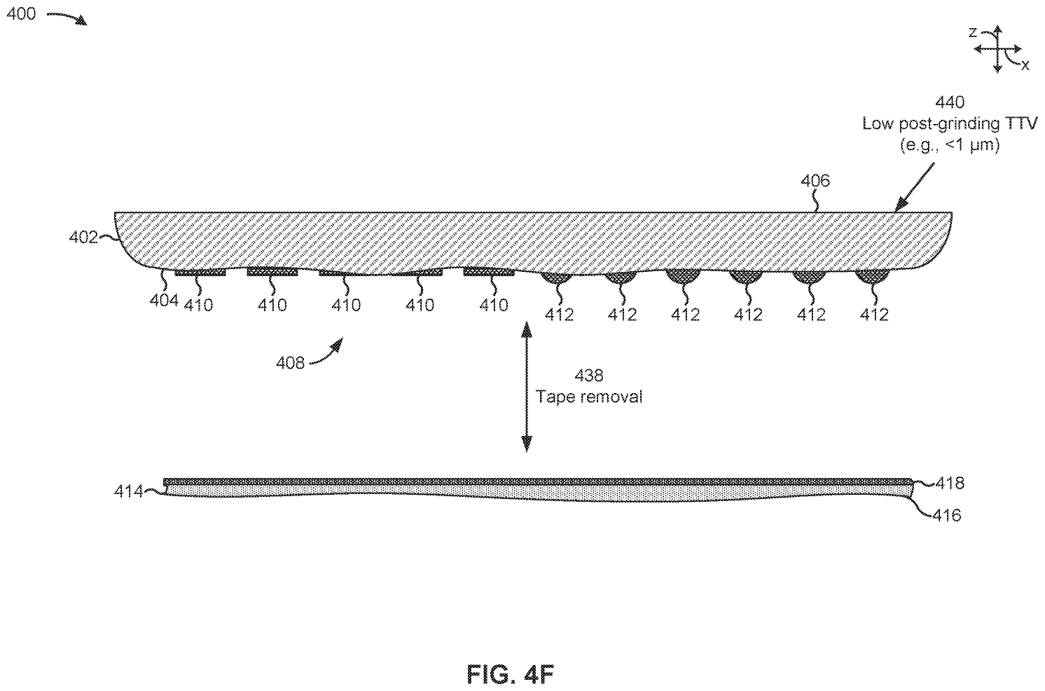

FIGS. 4A-4F show an example back grinding process 400 using a crosslinked back grinding tape that may be used to create a semiconductor die with a reduced TTV.

In the example back grinding process 400 shown in FIGS. 4A-4F, a back grinding tape having soft, liquid-like mechanical properties may be used during a back grinding process. The back grinding tape may thus be configured to flatten with little variation when subjected to pressure, thereby reducing a TTV of the back grinding tape and thus a TTV of the post-grinding semiconductor wafer. The back grinding tape may include one or more viscoelastic based materials that, when subjected to oscillatory stress, have a damping factor (e.g., a ratio of an elastic modulus, sometimes referred to as E′, to a viscous modulus, sometimes referred to as E″) of less than 0.8. Additionally, or alternatively, the back grinding tape may be either chemically modified and/or include chemical additives in order to include infrared-activated crosslinking groups or thermally activated crosslinking groups. In such implementations, a rigidity of the back grinding tape may be controlled by crosslinking the back grinding tape via heat and/or infrared irradiation. In this way, by subjecting the back grinding tape to sufficient pressure and/or inducing crosslinking may achieve specific mechanical properties allowing the back grinding tape may sufficiently absorb stresses generated during a back grinding process and/or may contribute to a reduced TTV of a post-grinding semiconductor wafer.

More particularly, FIG. 4A shows an example semiconductor wafer 402 that may undergo a back grinding process according to some implementations described herein. The semiconductor wafer 402 may be formed from any suitable semiconductor material, such as silicon or a similar semiconductor material. In some implementations, the semiconductor wafer 402 may be used to create multiple copies of an IC that may later be diced from the semiconductor wafer 402, forming multiple semiconductor dies. For example, the semiconductor wafer 402 may be used for form multiple copies of ICs and/or dies associated with a memory device, a flash memory device, a NAND memory device, a NOR memory device, a RAM device, a ROM device, a DRAM device, an SRAM device, an SDRAM device, an FeRAM device, an MRAM device, an RRAM device, an HRAM device, an SSD, a microchip, and/or an SoC, among other examples.

In some implementations, the semiconductor wafer 402 may include a pair of faces, such as a first face 404 and an opposing, second face 406. Each face 404, 406 may be a substantially flat, circular face having a diameter of in a range of approximately 25 millimeters (mm) to 300 mm, or greater. In some implementations, one of the faces 404, 406 may include one or more circuit elements, such as one or more electrical contacts configured to form an electrical connection with a corresponding electrical contact on a printed circuit board (PCB) or other component in a semiconductor package or similar assembly. For example, in the implementation shown in FIG. 4A, the first face may include one or more circuit elements 408, including a plurality of bond pads 410, a plurality of bumps 412, and/or other electrical contacts and/or circuit elements.

In some implementations, the semiconductor wafer 402 may undergo a back grinding process, such as to reduce a thickness of the semiconductor wafer 402 (e.g., a dimension of the semiconductor wafer 402 in the z-axis direction). In that regard, a back grinding tape, such as back grinding tape 414, may be mounted to the semiconductor wafer 402, such as for purposes of protecting the one or more circuit elements 408 during the back grinding process, ensuring against semiconductor wafer 402 surface damage during the back grinding process, and/or preventing semiconductor wafer 402 surface contamination caused by infiltration of grinding fluid and/or other contaminants during the back grinding process.

In some implementations, the back grinding tape 414 may include a polymer base layer 416 and an adhesive layer 418 configured to adhere the back grinding tape 414 to the semiconductor wafer 402. For example, the polymer base layer 416 may include a PET composite layer, and/or may be formed or include any other suitable polymer material. In some implementations, the adhesive layer 418 may include an acrylic layer and/or may include a UV curable adhesive layer. In such implementations, when the back grinding tape 414 is mounted to the semiconductor wafer 402 (which is described in more detail below in connection with FIG. 4B), the UV curable adhesive layer may be disposed between the PET composite layer and the semiconductor wafer 402. Additionally, or alternatively, the back grinding tape 414 may be formed with soft mechanical materials and/or viscoelastic materials, such that the back grinding tape exhibits a damping ratio of 0.8 or less.

In some implementations, the back grinding tape 414 may include infrared-activated crosslinking groups or thermally activated crosslinking groups. For example, the back grinding tape 414 (more particularly, the base layer 416 of the back grinding tape) may be modified to include the infrared-activated crosslinking groups and/or thermally activated crosslinking groups. In some implementations, a crosslink may refer to a bond (e.g., a covalent bond) or a short sequence of bonds that link one polymer chain to another. Thus, crosslinking may refer to a process of chemically joining two or more polymer chains by a bond (e.g., a covalent bond). In that regard, the back grinding tape 414 may include polymer chains that are configured to crosslink upon application of infrared irradiation (e.g., infrared-activated crosslinking groups) and/or upon application of heat (e.g., thermally activated crosslinking groups), among other examples. In some implementations, the back grinding tape 414 may be formed from materials that are capable of being crosslinked and/or the back grinding tape 414 may include materials that are capable of being crosslinked. For example, the back grinding tape 414 may be formed from and/or include a polymer that is chemically modified by attached reactive precursors and/or functional groups, such as acrylates, asides, azo group, epoxides, pyrazole, or the like, which, when subjected stimulation (e.g., photo-based stimulation and/or thermally based stimulation) activate to form reactive species that can react with polymer back bone (e.g., C—C insertion) or with the functional group at the end of the polymer chain (e.g., R—OH, R—COOH, or the like, where R is the polymer chain).

In such implementations, a degree of crosslinking associated with the back grinding tape 414 may be configured to vary according to at least one of an amount of heat applied to the back grinding tape or an amount of infrared light applied to the back grinding tape. A degree of crosslinking (sometimes referred to herein as a crosslinking density) may refer to a percentage of polymer chains that are crosslinked in the back grinding tape 414. In some implementations, the higher the degree of crosslinking, the more rigid the back grinding tape 414 will become. Accordingly, the back grinding tape 414 may be configured to have a varying rigidity based on an extent to which the back grinding tape 414 is crosslinked (e.g., based on how much infrared irradiation is applied for infrared-activated crosslinking groups and/or based on how much heat is applied for thermally activated crosslinking groups).

In some implementations, the back grinding tape 414 may be chemically modified in order to produce the infrared-activated crosslinking groups and/or the thermally activated crosslinking groups. For example, in some implementations, the polymer base layer 416 (e.g., the PET composite layer) may include chemical additives that produce at least one of infrared-activated crosslinking groups or thermally activated crosslinking groups. Additionally, or alternatively, the back grinding tape 414 may be chemically modified such that the back grinding tape 414 includes the infrared-activated crosslinking groups.

As shown in FIG. 4B, prior to a back grinding process, the back grinding tape 414 may be mounted to (e.g., laminated on) the semiconductor wafer 402. More particularly, as shown by reference number 420, the back grinding tape 414 may be mounted on the semiconductor wafer 402 by adhering the back grinding tape 414 (more particularly, the adhesive layer 418 of the back grinding tape 414) to the first face 404 of the semiconductor wafer 402 (e.g., the face of the semiconductor wafer 402 including the one or more circuit elements 408). In this way, the back grinding tape 414 may be mounted to the semiconductor wafer 402 in such a way that the back grinding tape 414 covers the one or more circuit elements 408 and/or protects the one or more circuit elements 408 during the back grinding process.

As shown by reference number 422, in some implementations, the back grinding tape 414 may be pressed onto the semiconductor wafer 402. Put another way, and as best seen by comparing the contour (e.g., the z-axis dimension) of the back grinding tape 414 in the example assembly indicated by reference number 420 with the contour of the back grinding tape 414 in the example assembly indicated by reference number 424, the back grinding tape 414 may be flattened by applying pressure to the back grinding tape 414. In some implementations, the back grinding tape 414 may be flattened by applying pressure to the back grinding tape 414 using a tape roller used to mount the back grinding tape 414 to the semiconductor wafer 402. Additionally, or alternatively, the back grinding tape 414 may be flattened by applying pressure to the back grinding tape 414 using a pressure chamber. For example, the semiconductor wafer 402 with the back grinding tape 414 mounted thereto may be placed in a pressure chamber such that a uniform pressure and/or load may be applied onto the semiconductor wafer 402 and back grinding tape 414. In some implementations, applying pressure (e.g., using the tape roller and/or a pressure chamber) may serve to at least partially crosslink the back grinding tape 414 (and thus may uniformly crosslink the back grinding tape 414 across the semiconductor wafer 402 when a uniform pressure chamber is utilized), may serve to improve adhesion of the back grinding tape 414 to the semiconductor wafer 402, and/or may serve to fully encompass and/or cushion the one or more circuit elements 408 disposed on the first face 404 of the semiconductor wafer 402.

As shown in FIG. 4C, in some implementations, the back grinding tape 414 may be crosslinked to thereby increase a rigidity of the back grinding tape 414, such as by IR crosslinking 426 and/or by thermal crosslinking 428. In some implementations, such as in implementations in which the back grinding tape 414 includes infrared-activated crosslinking groups, crosslinking the back grinding tape 414 may include applying infrared light to the back grinding tape 414, such as via an infrared (IR) lamp 430. Additionally, or alternatively, in some implementations, such as in implementations in which the back grinding tape 414 includes thermally activated crosslinking groups, crosslinking the back grinding tape 414 may include applying heat to the back grinding tape 414, such as via a heater 432.

Moreover, in some implementations, crosslinking the back grinding tape 414 may be performed during the back grinding tape 414 application process (e.g., during a process when the back grinding tape 414 is mounted to and/or laminated on the semiconductor wafer 402). For example, a tape roller used to the apply the back grinding tape 414 may include the heater 432 or a similar heat source to raise the temperature of the back grinding tape 414 being applied to thereby induce crosslinking. Put another way, in some implementations, crosslinking the back grinding tape 414 may include applying heat to the back grinding tape 414 using a heater 432 associated with a tape roller used to mount the back grinding tape 414 to the semiconductor wafer 402. Additionally, or alternatively, a tape roller used to the apply the back grinding tape 414 may include a moving IR lamp 430 attached along with the roller to crosslink the back grinding tape 414 along with the movement of the roller. Put another way, in some implementations, crosslinking the back grinding tape 414 may be performed using an IR lamp 430 associated with a tape roller used to mount the back grinding tape 414 to the semiconductor wafer 402.

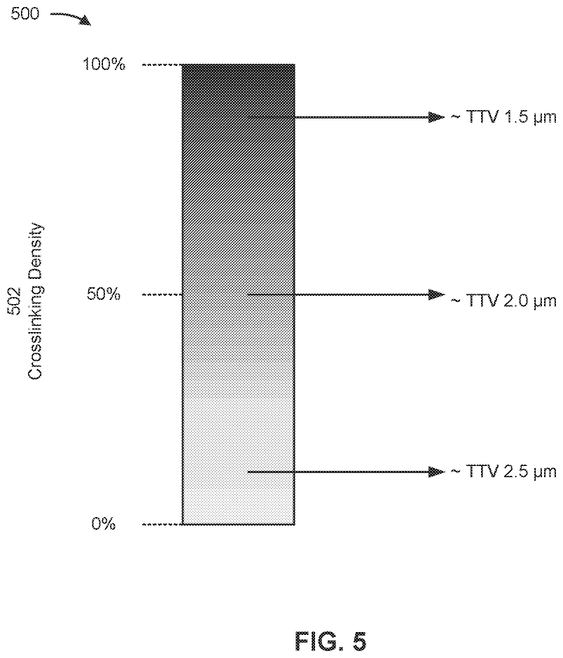

Additionally, or alternatively, in some implementations, crosslinking may be performed using a combination of infrared irradiation and thermal crosslinking, such as for purposes of achieving a variation of crosslink density across the wafer with uniform pressure due to roller pressure. That is, in some implementations, crosslinking the back grinding tape 414 may include applying infrared light to the back grinding tape 414 and applying heat to the back grinding tape 414. Moreover, an amount of heat and/or infrared light applied to the back grinding tape 414 may be controlled in an effort to control and/or vary TTVs or similar properties across the back grinding tape 414 and/or the semiconductor wafer 402. For example, in some implementations, crosslinking the back grinding tape 414 may include inducing a variation in crosslinking density across the first face 404 of the semiconductor wafer 402, while, in some other implementations, crosslinking the back grinding tape 414 may include inducing a substantially uniform crosslinking density across the first face 404 of the semiconductor wafer 402. In this way, by controlling properties of the back grinding tape 414 (e.g., a degree of crosslinking), an overall TTV of the semiconductor wafer 402 may also be controlled, such that a single back grinding tape 414 may be used for various device types (e.g., controllers, NAND devices, DRAM devices, or similar devices) and applications (e.g., bumped semiconductor wafers or non-bumped semiconductor wafers, among other examples). Details of using different crosslinking densities for different devices are described in more detail below in connection with FIG. 5.

As shown in FIG. 4D, once the back grinding tape 414 has been mounted to the semiconductor wafer 402, pressed against the semiconductor wafer 402, and/or crosslinked to a desired degree, the semiconductor wafer 402 may undergo a back grinding process in order to reduce a thickness (e.g., a z-axis dimension) of the semiconductor wafer 402. In some implementations, the back grinding process may include back grinding the semiconductor wafer 402 (e.g., using a grinding wheel 434 or similar grinding tool) by grinding the second face 406 until the semiconductor wafer 402 reaches a specific thickness. For example, for ultra-thin die applications or similar applications, back grinding the semiconductor wafer 402 may include back grinding the second face 406 until the semiconductor wafer 402 has a thickness of less than 60 μm.

In some implementations, the semiconductor wafer 402 may be secured to a rotary table (sometimes referred to as a chuck table) or similar apparatus during the back grinding process. For example, a side of the semiconductor wafer 402 including the back grinding tape 414 adhered thereto (e.g., the circuit side and/or frontside of the semiconductor wafer 402) may be secured to a corresponding chuck of a chuck table during the back grinding process. In some implementations, an angle of the chuck table may be adjusted during a back grinding process in order to achieve a sufficient TTV of the semiconductor wafer 402. For example, a grinding tool (e.g., grinding wheel 434) and a chuck table may be configured to communicate in a feedback loop such that a chuck table angle and/or grinding wheel parameters may be adjusted to correct a position of the semiconductor wafer 402 during the back grinding process and thereby reduce a TTV of the post-grinded semiconductor wafer 402.

In some implementations, the adhesive layer 418 of the back grinding tape 414 may be a UV curable adhesive layer, as described above in connection with FIG. 4A. In such implementations, after back grinding, UV light may be applied to the back grinding tape 414 to thereby cure the adhesive layer 418 and/or facilitate removal of the back grinding tape 414. More particularly, as shown in FIG. 4E, UV light may be applied to the back grinding tape via a UV lamp 436 or similar device, thereby curing the adhesive layer 418.

As shown in FIG. 4F, and as indicated by reference number 438, following back grinding (and, when applicable, application of the UV light), the back grinding tape 414 may be removed from the first face 404 of the semiconductor wafer 402 to thereby expose the one or more circuit elements 408 (e.g., the bond pads 410, the bumps 412, and/or other electrical contacts or circuit elements). As shown by reference number 440, based on pressing the back grinding tape 414 to the semiconductor wafer, as described in detail above in connection with FIG. 4B, and/or based on crosslinking the back grinding tape 414, as described in detail above in connection with FIG. 4C, the semiconductor wafer 402 may exhibit an improved post-grinding TTV as compared to the post-grinding TTV of the semiconductor wafer 302 described in connection with FIG. 3 and/or semiconductor wafers formed using similar processes. More particularly, in some implementations, a TTV associated with the semiconductor wafer 402 may be less than approximately 1 μm. In some other implementations, a TTV of the semiconductor wafer 402 may differ based on amount of crosslinking performed and/or a specific type of die being formed from the semiconductor wafer 402, which is described in more detail below in connection with FIG. 5.

As indicated above, FIGS. 4A-4F are provided as examples. Other examples may differ from what is described with regard to FIGS. 4A-4F.

FIG. 5 is a diagram of an example 500 associated with varying a crosslinking density according to a type of semiconductor die being formed by a semiconductor wafer.

As shown by reference number 502, a crosslinking density (e.g., a crosslinking degree) of the back grinding tape 414 may be configurable such that a higher or lower crosslinking degree may be achieved based on a type of die being formed from the semiconductor wafer 402, among other factors. For example, for ultra-thin dies that may be stacked in an mNAND device, an MCP, or a similar semiconductor package, a degree of crosslinking may be relatively high in order to achieve a relatively low TTV. On the other hand, for thicker dies and/or dies that may not be stacked in an mNAND device, an MCP, or a similar semiconductor package, a degree of crosslinking may be relatively low.

More particularly, in some implementations, the semiconductor wafer 402 may be associated with a plurality of memory controller dies, such as a plurality of controllers 215 (e.g., the semiconductor wafer 402 may be used form a plurality of copies of the controller 215). In such implementations, crosslinking the back grinding tape 414 may include crosslinking the back grinding tape 414 to a crosslinking density of less than 50 percent. In some implementations, and as shown in FIG. 5, this may result in a TTV of approximately 2.5 μm.

In some other implementations, the semiconductor wafer 402 may be associated with a plurality of DRAM dies, such as a plurality of volatile memory 210 dies (e.g., the semiconductor wafer 402 may be used form a plurality of copies of the volatile memory 210 dies). In such implementations, crosslinking the back grinding tape 414 may include crosslinking the back grinding tape 414 to a crosslinking density in a range of approximately 40 percent to approximately 60 percent. More particularly, crosslinking the back grinding tape 414 may include crosslinking the tape to a crosslinking density in of approximately 50 percent. In some implementations, and as shown in FIG. 5, this may result in a TTV of approximately 2.0 μm.

In some other implementations, the semiconductor wafer 402 may be associated with a plurality of NAND memory dies, such as a plurality of the non-volatile memory 205 dies (e.g., the semiconductor wafer 402 may be used form a plurality of copies of the non-volatile memory 205 dies). In such implementations, crosslinking the back grinding tape 414 may include crosslinking the back grinding tape 414 to a crosslinking density of greater than 50 percent. In some implementations, and as shown in FIG. 5, this may result in a TTV of approximately 1.5 μm. In sum, different technology wafers may achieve different TTVs using the same back grinding tape 414 by achieving a specific crosslink density in the back grinding tape 414 that corresponds to the particular application.

In that regard, the back grinding tape 414 may be exhibit an ability to tune a TTV of a post-grinding semiconductor wafer 402 by controlling an amount of crosslinking performed on the back grinding tape 414. In some implementations, the back grinding tape 414 may result in uniform TTV tunability by controlling the crosslinking of back grinding tape 414. Additionally, or alternatively, by forming the back grinding tape 414 from an initial (e.g., pre-crosslinking) viscoelastic material, when the back grinding tape 414 is subjected to pressure (e.g., before crosslinking), the back grinding tape 414 may induce better wetting and bump coverage without inducing damage, resulting in lower or complete elimination of voids between the back grinding tape 414 and the face of the semiconductor wafer 402 including the one or more circuit elements 408. Moreover, a back grinding tape 414 exhibiting a varying degree of crosslinking may permit better semiconductor wafer 402 stress-handling and/or may prevent semiconductor wafer 402 breakage during processing steps, such as during the back grinding step. Additionally, a TTV tunability of the back grinding tape 414, as described in connection with FIG. 5, may permit a single back grinding tape 414 to be applied across numerous devices and application types (e.g., bumped and non-bumped wafers), while achieving sub-1 μm TTV for certain ultra-thin dies or similar applications.

As indicated above, FIG. 5 is provided as an example. Other examples may differ from what is described with regard to FIG. 5.

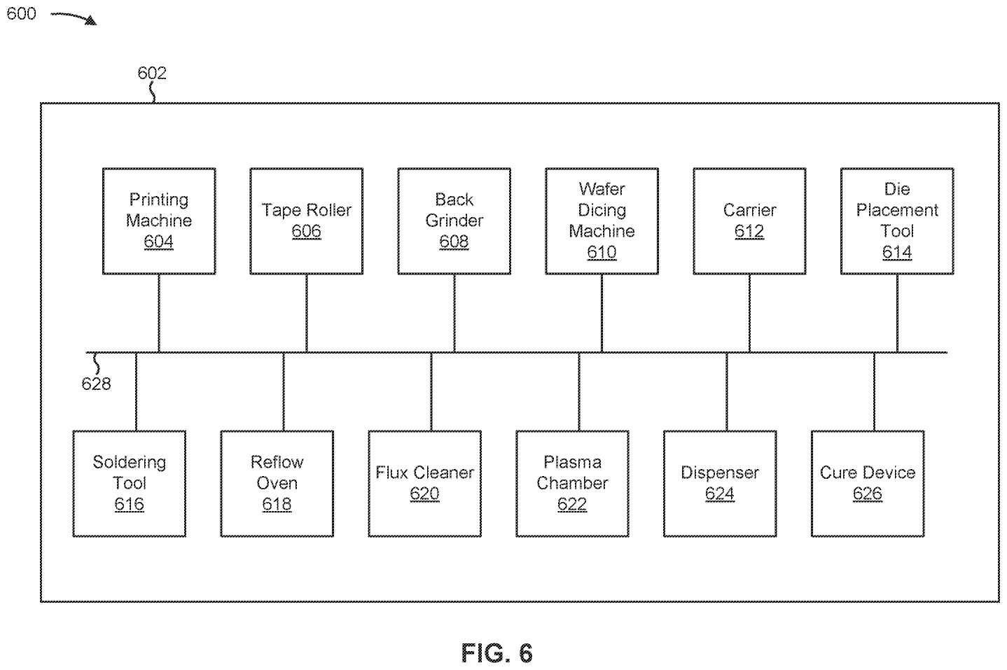

FIG. 6 is a diagram of example equipment 600 used to manufacture various semiconductor packages, memory devices, or similar components described herein. In some implementations, the equipment 600 may be used to perform the fabrication steps described above in connection with the example back grinding process 400, and/or the equipment 600 may be used to fabricate a memory package or other semiconductor package or assembly including components described in connection with the example back grinding process 400 (e.g., the semiconductor wafer 402 and/or the back grinding tape 414). As shown in FIG. 6, the equipment 600 may include a packaging system 602. The packaging system 602 may include one or more devices or tooling, such as a printing machine 604, a tape roller 606, a back grinder 608, a wafer dicing machine 610, a carrier 612, a die placement tool 614, a soldering tool 616, a reflow oven 618, a flux cleaner 620, a plasma chamber 622, a dispenser 624, and/or a cure device 626. One or more devices may be may physically or communicatively coupled to one another. For example, one or more devices may interconnect via wired connections and/or wireless connections, such as via a bus 628. Additionally, or alternatively, one or more devices may form part of an electronics assembly manufacturing line.

The printing machine 604 may be a device capable of printing patterns in a material and/or depositing materials on a material. In some implementations, the printing machine 604 may be capable of applying solder or other electrically conductive material to form a portion of an electrical connection to be formed between a die and a substrate. For example, the printing machine 604 may be capable of applying a grid of solder bumps to a die, such as on a flip-chip die or similar die, which will align with a grid of bump pads on a substrate during a flip chip attachment process, or the like.

The tape roller 606 may be a device capable of laminating a tape (e.g., a back grinding tape) on a semiconductor wafer and/or a semiconductor die. The tape roller 606 may be capable of applying pressure to a tape as the tape is being laminated onto a wafer or a die. The tape roller 606 may include additional components, such as an infrared lamp (e.g., IR lamp 430), a heater (e.g., heater 432), or similar components, such as for purposes of crosslinking a back grinding tape during lamination of the back grinding tape onto a wafer or die. In some implementations, the tape roller 606 may be associated with a chamber, such as a pressure chamber used to apply a uniform pressure to a back grinding tape after the back grinding tape has been laminated onto a wafer.

The back grinder 608 may be a device capable of grinding a backside of a semiconductor wafer and/or a semiconductor die, thereby reducing a thickness of the wafer and/or a die to a desired thickness. In some implementations, the back grinder 608 may be associated with a rotary table, a chuck table, and/or a grinding wheel (e.g., grinding wheel 434) for purposes of grinding a wafer and/or a die to a suitable thickness.

The wafer dicing machine 610 may be a device capable of dicing a die, such as a microcontroller, a memory die, or other semiconductor die, from a wafer. In some implementations, the wafer dicing machine 610 may include one or more blades and/or one or more lasers to dice a die from the wafer.

The carrier 612 may be a device capable of supporting and/or carrying a substrate during a die and/or chip attachment process, during a compression molding process, or during a similar process. The carrier 612 may be constructed from a non-contaminating material, such as quartz, glass, or a similar material, and may be capable of withstanding high temperatures. In that regard, the carrier 612 may be capable of carrying a substrate and/or one or more die through one or more ovens, such as a reflow oven 618 and/or a cure device 626.

The die placement tool 614 may be a high-precision tool capable of placing a die onto a substrate. In some implementations, the die placement tool 614 may be capable of flipping a flip chip die during a placement process, such that an active surface of the flip chip die, which may be facing up during preliminary manufacturing steps, may face the substrate during the flip chip die placement process. In some implementations, the die placement tool 614 may include one or more sensors capable of aligning bump bonds on a die with bond pads on a substrate during a flip chip die attachment process.

The soldering tool 616 may be capable of forming one or more solder connections between components of a semiconductor package. For example, the soldering tool 616 may be capable of forming wire bond connections between components of a semiconductor package by soldering wires connecting wire bond bands from one component to wire bond pads of another component. In some examples, the soldering tool 616 may be capable of applying a solder paste to between electrical contacts of electronic components, such as between pillar interconnects provided on a load switch and corresponding electrical contacts provided on a substrate.

The reflow oven 618 may be a device capable of heating components to a suitable temperature to cause a reflow of solder or other bonding material, thereby causing the solder or similar material to melt and make an electrical connection between two components.

The flux cleaner 620 may be a device capable of removing residual flux from a soldering process. In some implementations, the flux cleaner 620 may include a heater capable of removing residual flux through a heat treatment process. Additionally, or alternatively, the flux cleaner 620 may include a nozzle or similar device capable of applying a cleaning agent to a component in order to remove residual flux therefrom.

The plasma chamber 622 may be a device capable of providing plasma treatment to component. In some implementations, the plasma chamber 622 may be capable of directly or indirectly applying a plasma stream to an area of a component, such as for purposes of preparing the area on the component for receiving an epoxy underfill, or the like.

The dispenser 624 may be a device capable of dispensing a filler material around a die or similar component. In some implementations, the dispenser 624 may be capable of dispensing a mold compound (e.g., an epoxy mold compound) during a compression molding process. In some implementations, the dispenser 624 may include a dispensing needle capable of applying an epoxy underfill by capillary action under pressure, such as by dispensing underfill material around a periphery of a die and/or other electrical component such that the underfill material flows beneath the die and/or other electrical component and fills a space between the die and/or other electrical component and a substrate.

The cure device 626 may be a device capable of curing a material, such as a UV curable adhesive layer, a mold compound, such as an epoxy mold compound, an epoxy underfill material, a moldable underfill material, or a similar material. In some implementations, the cure device 626 may include a UV lamp (e.g., UV lamp 436) capable of irradiating a back grinding tape with UV light in order to cure an adhesive layer thereof. In some implementations, the cure device 626 may be an oven configured to heat a mold compound to a suitable curing temperature. Additionally, or alternatively, the cure device 626 may be capable of curing a mold compound via a chemical reaction, by the application of ultraviolet light, by the application of other radiation, or the like.

The number and arrangement of devices and networks shown in FIG. 6 are provided as an example. In practice, there may be additional devices, fewer devices, different devices, or differently arranged devices than those shown in FIG. 6. Furthermore, two or more devices shown in FIG. 6 may be implemented within a single device, or a single device shown in FIG. 6 may be implemented as multiple, distributed devices. Additionally, or alternatively, a set of devices (e.g., one or more devices) of equipment 600 may perform one or more functions described as being performed by another set of devices of equipment 600.

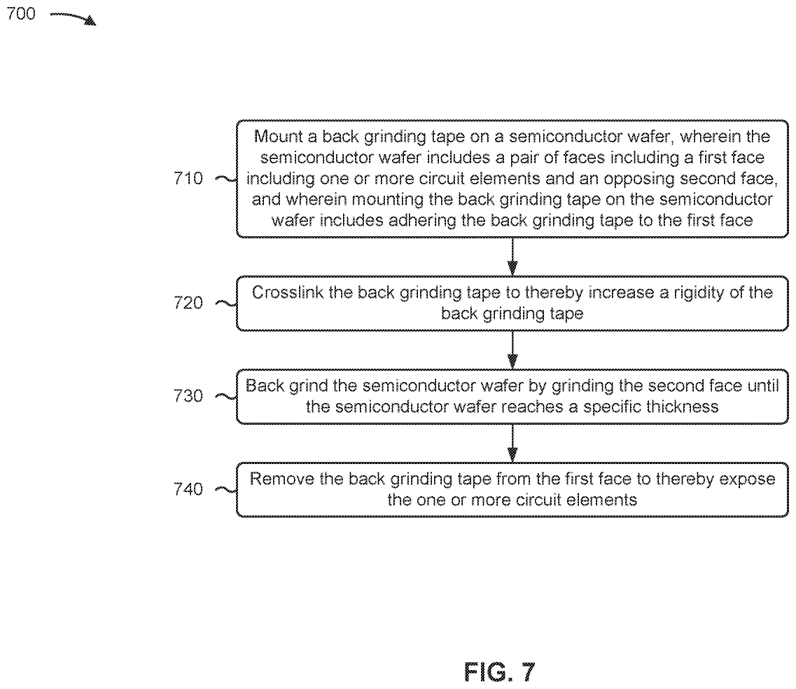

FIG. 7 is a flowchart of an example method 700 of forming an integrated assembly or memory device having a reduced TTV. In some implementations, one or more process blocks of FIG. 7 may be performed by various semiconductor manufacturing equipment, such as the semiconductor manufacturing equipment described above in connection with FIG. 6 or similar semiconductor manufacturing equipment.

As shown in FIG. 7, the method 700 may include mounting a back grinding tape on a semiconductor wafer, wherein the semiconductor wafer includes a pair of faces including a first face including one or more circuit elements and an opposing second face, and wherein mounting the back grinding tape on the semiconductor wafer includes adhering the back grinding tape to the first face (block 710). As further shown in FIG. 7, the method 700 may include crosslinking the back grinding tape to thereby increase a rigidity of the back grinding tape (block 720). As further shown in FIG. 7, the method 700 may include back grinding the semiconductor wafer by grinding the second face until the semiconductor wafer reaches a specific thickness (block 730). As further shown in FIG. 7, the method 700 may include removing the back grinding tape from the first face to thereby expose the one or more circuit elements (block 740).

The method 700 may include additional aspects, such as any single aspect or any combination of aspects described below and/or in connection with one or more other methods described elsewhere herein.

In a first aspect, the method 700 includes flattening the back grinding tape by applying pressure to the back grinding tape.

In a second aspect, alone or in combination with the first aspect, applying pressure to the back grinding tape includes applying pressure with a tape roller used to mount the back grinding tape to the semiconductor wafer.

In a third aspect, alone or in combination with one or more of the first and second aspects, applying pressure to the back grinding tape includes applying pressure using a pressure chamber.

In a fourth aspect, alone or in combination with one or more of the first through third aspects, crosslinking the back grinding tape includes inducing a variation in crosslinking density across the first face.

In a fifth aspect, alone or in combination with one or more of the first through fourth aspects, crosslinking the back grinding tape includes inducing a substantially uniform crosslinking density across the first face.

In a sixth aspect, alone or in combination with one or more of the first through fifth aspects, crosslinking the back grinding tape includes applying heat to the back grinding tape.

In a seventh aspect, alone or in combination with one or more of the first through sixth aspects, applying heat to the back grinding tape is performed using a heater associated with a tape roller used to mount the back grinding tape to the semiconductor wafer.

In an eighth aspect, alone or in combination with one or more of the first through seventh aspects, crosslinking the back grinding tape includes applying infrared light to the back grinding tape.

In a ninth aspect, alone or in combination with one or more of the first through eighth aspects, applying infrared light to the back grinding tape is performed using an infrared lamp associated with a tape roller used to mount the back grinding tape to the semiconductor wafer.

In a tenth aspect, alone or in combination with one or more of the first through ninth aspects, crosslinking the back grinding tape includes applying infrared light to the back grinding tape and applying heat to the back grinding tape.

In an eleventh aspect, alone or in combination with one or more of the first through tenth aspects, back grinding the semiconductor wafer includes back grinding the second face until the semiconductor wafer has a thickness of less than 40 micrometers.

In a twelfth aspect, alone or in combination with one or more of the first through eleventh aspects, a total thickness variation associated with the semiconductor wafer is less than approximately 1 micrometer.

In a thirteenth aspect, alone or in combination with one or more of the first through twelfth aspects, the semiconductor wafer is associated with a plurality of dynamic random access memory dies, and wherein crosslinking the back grinding tape includes crosslinking the back grinding tape to a crosslinking density in a range of approximately 40 percent to approximately 60 percent.

In a fourteenth aspect, alone or in combination with one or more of the first through thirteenth aspects, the semiconductor wafer is associated with a plurality of NAND memory dies, and wherein crosslinking the back grinding tape includes crosslinking the back grinding tape to a crosslinking density of greater than 50 percent.

In a fifteenth aspect, alone or in combination with one or more of the first through fourteenth aspects, the semiconductor wafer is associated with a plurality of memory controller dies, and wherein crosslinking the back grinding tape includes crosslinking the back grinding tape to a crosslinking density of less than 50 percent.

In a sixteenth aspect, alone or in combination with one or more of the first through fifteenth aspects, removing the back grinding tape from the first face includes applying ultraviolet light to the back grinding tape.

Although FIG. 7 shows example blocks of the method 700, in some implementations, the method 700 may include additional blocks, fewer blocks, different blocks, or differently arranged blocks than those depicted in FIG. 7. In some implementations, the method 700 may include forming the semiconductor wafer 402 and back grinding tape 414 assembly described in connection with FIGS. 4A-4F, an integrated assembly that includes the semiconductor wafer 402 and back grinding tape 414 assembly described in connection with FIGS. 4A-4F, any part described herein of the semiconductor wafer 402 and back grinding tape 414 assembly described in connection with FIGS. 4A-4F, and/or any part described herein of an integrated assembly that includes the semiconductor wafer 402 and back grinding tape 414 assembly described in connection with FIGS. 4A-4F. For example, the method 700 may include forming one or more of the semiconductor wafer 402 and/or the back grinding tape 414.

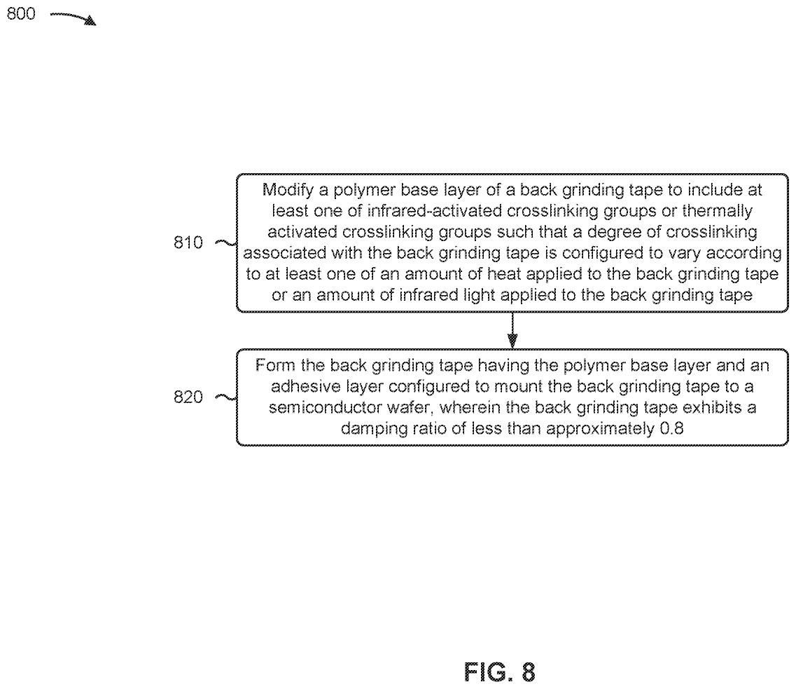

FIG. 8 is a flowchart of an example method 800 of forming an integrated assembly or memory device having a reduced TTV. In some implementations, one or more process blocks of FIG. 8 may be performed by various semiconductor manufacturing equipment, such as the semiconductor manufacturing equipment described above in connection with FIG. 6 or similar semiconductor manufacturing equipment.

As shown in FIG. 8, the method 800 may include modifying a polymer base layer of a back grinding tape to include at least one of infrared-activated crosslinking groups or thermally activated crosslinking groups such that a degree of crosslinking associated with the back grinding tape is configured to vary according to at least one of an amount of heat applied to the back grinding tape or an amount of infrared light applied to the back grinding tape (block 810). As further shown in FIG. 8, the method 800 may include forming the back grinding tape having the polymer base layer and an adhesive layer configured to adhere the back grinding tape to a semiconductor wafer, wherein the back grinding tape exhibits a damping ratio of less than approximately 0.8 (block 820).

The method 800 may include additional aspects, such as any single aspect or any combination of aspects described below and/or in connection with one or more other methods described elsewhere herein.

In a first aspect, modifying the polymer base layer includes chemically modifying the polymer base layer such that the polymer base layer includes the infrared-activated crosslinking groups.

In a second aspect, alone or in combination with the first aspect, modifying the polymer base layer includes applying chemical additives to the polymer base layer such that the polymer base layer includes the thermally activated crosslinking groups.

In a third aspect, alone or in combination with one or more of the first and second aspects, a degree of crosslinking associated with the back grinding tape is configured to vary between less than 50 percent in a case where the back grinding tape is used to form memory controller dies, a range of approximately 40 percent to approximately 60 percent in a case where the back grinding tape is used to form dynamic random access memory dies, and greater than 50 percent in a case where the back grinding tape is used to form NAND memory dies.

Although FIG. 8 shows example blocks of the method 800, in some implementations, the method 800 may include additional blocks, fewer blocks, different blocks, or differently arranged blocks than those depicted in FIG. 8. In some implementations, the method 800 may include forming the back grinding tape 414 described in connection with FIGS. 4A-4F.

In some implementations, a method includes mounting a back grinding tape on a semiconductor wafer, wherein the semiconductor wafer includes a pair of faces including a first face including one or more circuit elements and an opposing second face, and wherein mounting the back grinding tape on the semiconductor wafer includes adhering the back grinding tape to the first face; crosslinking the back grinding tape to thereby increase a rigidity of the back grinding tape; back grinding the semiconductor wafer by grinding the second face until the semiconductor wafer reaches a specific thickness; and removing the back grinding tape from the first face to thereby expose the one or more circuit elements.

In some implementations, a method includes modifying a polymer base layer of a back grinding tape to include at least one of infrared-activated crosslinking groups or thermally activated crosslinking groups such that a degree of crosslinking associated with the back grinding tape is configured to vary according to at least one of an amount of heat applied to the back grinding tape or an amount of infrared light applied to the back grinding tape; and forming the back grinding tape having the polymer base layer and an adhesive layer configured to adhere the back grinding tape to a semiconductor wafer, wherein the back grinding tape exhibits a damping ratio of less than approximately 0.8.

In some implementations, a back grinding tape includes a polymer base layer; and an adhesive layer configured to adhere the back grinding tape to a face of a semiconductor wafer, wherein the back grinding tape exhibits a damping ratio of less than approximately 0.8, and wherein the back grinding tape includes at least one of infrared-activated crosslinking groups or thermally activated crosslinking groups such that a degree of crosslinking associated with the back grinding tape is configured to vary according to at least one of an amount of heat applied to the back grinding tape or an amount of infrared radiation applied to the back grinding tape.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method, comprising:
mounting a back grinding tape on a semiconductor wafer, wherein the semiconductor wafer includes a pair of faces including a first face including one or more circuit elements and an opposing second face, and wherein mounting the back grinding tape on the semiconductor wafer includes adhering the back grinding tape to the first face;
crosslinking the back grinding tape to thereby increase a rigidity of the back grinding tape;
back grinding the semiconductor wafer by grinding the second face until the semiconductor wafer reaches a specific thickness; and
removing the back grinding tape from the first face to thereby expose the one or more circuit elements.

2. The method of claim 1, further comprising flattening the back grinding tape by applying pressure to the back grinding tape.

3. The method of claim 2, wherein applying pressure to the back grinding tape includes applying pressure with a tape roller used to mount the back grinding tape to the semiconductor wafer.

4. The method of claim 2, wherein applying pressure to the back grinding tape includes applying pressure using a pressure chamber.

5. The method of claim 1, wherein crosslinking the back grinding tape includes inducing a variation in crosslinking density across the first face.

6. The method of claim 1, wherein crosslinking the back grinding tape includes inducing a substantially uniform crosslinking density across the first face.

7. The method of claim 1, wherein crosslinking the back grinding tape includes applying heat to the back grinding tape.

8. The method of claim 7, wherein applying heat to the back grinding tape is performed using a heater associated with a tape roller used to mount the back grinding tape to the semiconductor wafer.

9. The method of claim 1, wherein crosslinking the back grinding tape includes applying infrared light to the back grinding tape.

10. The method of claim 9, wherein applying infrared light to the back grinding tape is performed using an infrared lamp associated with a tape roller used to mount the back grinding tape to the semiconductor wafer.

11. The method of claim 1, wherein crosslinking the back grinding tape includes applying infrared light to the back grinding tape and applying heat to the back grinding tape.

12. The method of claim 1, wherein back grinding the semiconductor wafer includes back grinding the second face until the semiconductor wafer has a thickness of less than 40 micrometers.

13. The method of claim 12, wherein a total thickness variation associated with the semiconductor wafer is less than approximately 1 micrometer.

14. The method of claim 1, wherein the semiconductor wafer is associated with a plurality of dynamic random access memory dies, and wherein crosslinking the back grinding tape includes crosslinking the back grinding tape to a crosslinking density in a range of approximately 40 percent to approximately 60 percent.

15. The method of claim 1, wherein the semiconductor wafer is associated with a plurality of NAND memory dies, and wherein crosslinking the back grinding tape includes crosslinking the back grinding tape to a crosslinking density of greater than 50 percent.

16. The method of claim 1, wherein the semiconductor wafer is associated with a plurality of memory controller dies, and wherein crosslinking the back grinding tape includes crosslinking the back grinding tape to a crosslinking density of less than 50 percent.

17. The method of claim 1, wherein removing the back grinding tape from the first face includes applying ultraviolet light to the back grinding tape.

18. A method, comprising:
modifying a polymer base layer of a back grinding tape to include at least one of infrared-activated crosslinking groups or thermally activated crosslinking groups such that a degree of crosslinking associated with the back grinding tape is configured to vary according to at least one of an amount of heat applied to the back grinding tape or an amount of infrared light applied to the back grinding tape; and
forming the back grinding tape having the polymer base layer and an adhesive layer configured to adhere the back grinding tape to a semiconductor wafer, wherein the back grinding tape exhibits a damping ratio of less than approximately 0.8.

19. The method of claim 18, wherein modifying the polymer base layer includes chemically modifying the polymer base layer such that the polymer base layer includes the infrared-activated crosslinking groups.

20. The method of claim 18, wherein modifying the polymer base layer includes applying chemical additives to the polymer base layer such that the polymer base layer includes the thermally activated crosslinking groups.

21. The method of claim 18, wherein a degree of crosslinking associated with the back grinding tape is configured to vary between:
less than 50 percent in a case where the back grinding tape is used to form memory controller dies,
a range of approximately 40 percent to approximately 60 percent in a case where the back grinding tape is used to form dynamic random access memory dies, and
greater than 50 percent in a case where the back grinding tape is used to form NAND memory dies.

22. A back grinding tape, comprising:
a polymer base layer; and
an adhesive layer configured to adhere the back grinding tape to a face of a semiconductor wafer,
wherein the back grinding tape exhibits a damping ratio of less than approximately 0.8, and
wherein the back grinding tape includes at least one of infrared-activated crosslinking groups or thermally activated crosslinking groups such that a degree of crosslinking associated with the back grinding tape is configured to vary according to at least one of an amount of heat applied to the back grinding tape or an amount of infrared radiation applied to the back grinding tape.

23. The back grinding tape of claim 22, wherein the adhesive layer is configured to adhere to one or more circuit elements of the semiconductor wafer, wherein the one or more circuit elements include at least one of bumps or bond pads.

24. The back grinding tape of claim 22, wherein the polymer base layer includes a polyethylene terephthalate (PET) composite layer, and wherein the adhesive layer includes an ultraviolet (UV) curable adhesive layer.

25. The back grinding tape of claim 24, wherein the PET composite layer includes chemical additives that produce the at least one of infrared-activated crosslinking groups or thermally activated crosslinking groups.
